(19) United States
(12) Patent Application Publication
(10) Pub. No.: US 2019/0165216 A1
(43) Pub. Date: May 30, 2019

(54) ULTRAVIOLET LIGHT EMITTING DEVICE PACKAGE

(71) Applicant: Samsung Electronics Co., Ltd., Suwon-si (KR)

(72) Inventors: Sam Mook KANG, Hwaseong-si (KR); Joo Sung Kim, Seongnam-si (KR); Mi Hyun Kim, Seoul (KR); Young Hwan Park, Yongin-si (KR)

(73) Assignee: Samsung Electronics Co., Ltd., Suwon-si (KR)

(21) Appl. No.: 15/986,120

(22) Filed: May 22, 2018

(30) Foreign Application Priority Data
Nov. 24, 2017 (KR) 10-2017-0158362

(51) Int. Cl. H01L 33/48; H01L 33/60; H01L 33/54; H01L 33/36; H01L 33/62; H01L 33/00

(52) U.S. Cl. CPC H01L 33/483; H01L 33/60; H01L 33/54; H01L 33/36; H01L 33/32; H01L 33/007; H01L 2933/0016; H01L 2933/005; H01L 2933/0066; H01L 33/62

(57) ABSTRACT

An ultraviolet light emitting device package, comprising: a growth substrate having a first surface, a second surface corresponding thereto, and a light emitting window penetrating through the first surface and the second surface, a reflective layer disposed on an internal wall of the light emitting window, a light transmissive cover disposed on the first surface and covering the light emitting window, a light emitting structure disposed on the second surface to cover the light emitting window and including a first conductivity-type semiconductor layer, a second conductivity-type semiconductor layer, and an active layer interposed between the first conductivity-type semiconductor layer and the second conductivity-type semiconductor layer, and a first electrode and a second electrode, connected to the first conductivity-type semiconductor layer and the second conductivity-type semiconductor layer, respectively.

### CROSS-REFERENCE TO RELATED APPLICATION

This application claims benefit of Korean Patent Application No. 10-2017-0158362 filed on Nov. 24, 2017, with the Korean Intellectual Property Office, the disclosure of which is incorporated herein by reference in its entirety.

### BACKGROUND

### 1. Field

The present inventive concepts relate to an ultraviolet light emitting device package.

### 2. Description of Related Art

Recently, ultraviolet (UV) light sources have been used for a variety of applications, such as in sterilizing devices, disinfection devices, and UV curing devices. Eco-friendly and high efficiency semiconductor light emitting devices (LEDs) have attracted attention as such ultraviolet light sources. For example, nitride semiconductor ultraviolet light emitting devices may be used.

However, since ultraviolet rays emitted by ultraviolet LEDs have a relatively high level of energy, ultraviolet rays may be easily absorbed by semiconductors, and light extraction efficiency may be relatively low.

### SUMMARY

An aspect of the present inventive concepts is to provide an ultraviolet light emitting device package having improved light extraction efficiency.

According to an aspect of the present inventive concepts, an ultraviolet light emitting device package includes a growth substrate having a first surface, a second surface corresponding thereto, and a light emitting window penetrating through the first surface and the second surface, a reflective layer disposed on an internal wall of the light emitting window, a light transmissive cover disposed on the first surface and covering the light emitting window, a light emitting structure disposed on the second surface to cover the light emitting window and including a first conductivity-type semiconductor layer, a second conductivity-type semiconductor layer, and an active layer interposed between the first conductivity-type semiconductor layer and the second conductivity-type semiconductor layer, and a first electrode and a second electrode, connected to the first conductivity-type semiconductor layer and the second conductivity-type semiconductor layer, respectively.

According to an aspect of the present inventive concepts, an ultraviolet light emitting device package includes a growth substrate, including at least one light emitting window penetrating through the growth substrate in a thickness direction, a reflective layer covering an internal wall of the at least one light emitting window, a light transmissive cover disposed on one surface of the growth substrate and covering the at least one light emitting window to form a blocked space, at least one light emitting structure disposed on the other surface of the growth substrate to cover the at least one light emitting window and including a first conductivity-type semiconductor layer, an active layer, and a second conductivity-type semiconductor layer, sequentially disposed on the other surface, and a first electrode and a second electrode, connected to the first conductivity-type semiconductor layer and the second conductivity-type semiconductor layer of the at least one light emitting structure, respectively.

According to an aspect of the present inventive concepts, an ultraviolet light emitting device package includes a light emitting structure including a first conductivity-type semiconductor layer, an active layer, and a second conductivity-type semiconductor layer, a growth substrate having one surface in contact with the light emitting structure, the other surface opposing the one surface, and a light emitting window defined by an internal wall penetrating through the one surface and the other surface, a reflective layer disposed to cover the internal wall, a light transmissive cover disposed on the other surface of the light emitting structure and covering the light emitting window, and a first electrode and a second electrode, connected to the first conductivity-type semiconductor layer and the second conductivity-type semiconductor layer, respectively.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view of an ultraviolet light emitting device package according to an example embodiment of the present inventive concepts;

FIG. 2 is a top view of an ultraviolet light emitting device package of FIG. 1 when viewed in an I direction;

FIG. 3 is a cross-sectional view of an ultraviolet light emitting device package taken along line II-IP of FIG. 2;

FIG. 4 is an enlarged view of portion ‘A’ of FIG. 3;

FIG. 5 is a top view of an ultraviolet light emitting device package according to an example embodiment of the present inventive concepts;

FIG. 6 is a cross-sectional view of an ultraviolet light emitting device package taken along line of FIG. 5; and

FIGS. 7 to 17 are schematic cross-sectional views of a process of manufacturing an ultraviolet light emitting device package of FIG. 3.

### DETAILED DESCRIPTION

Hereinafter, example embodiments of the present inventive concepts will be described with reference to the accompanying drawings.

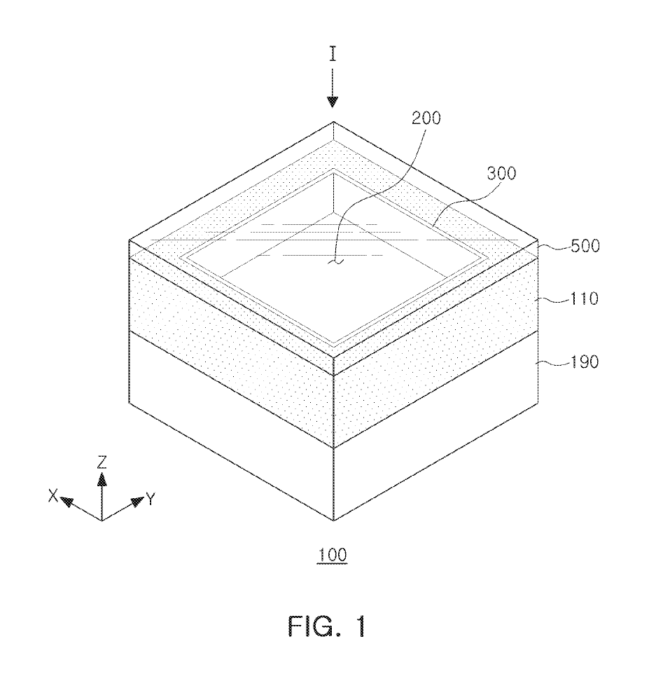

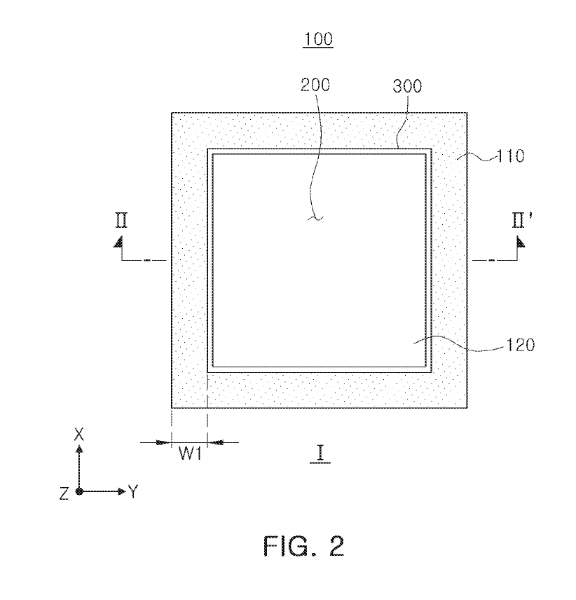

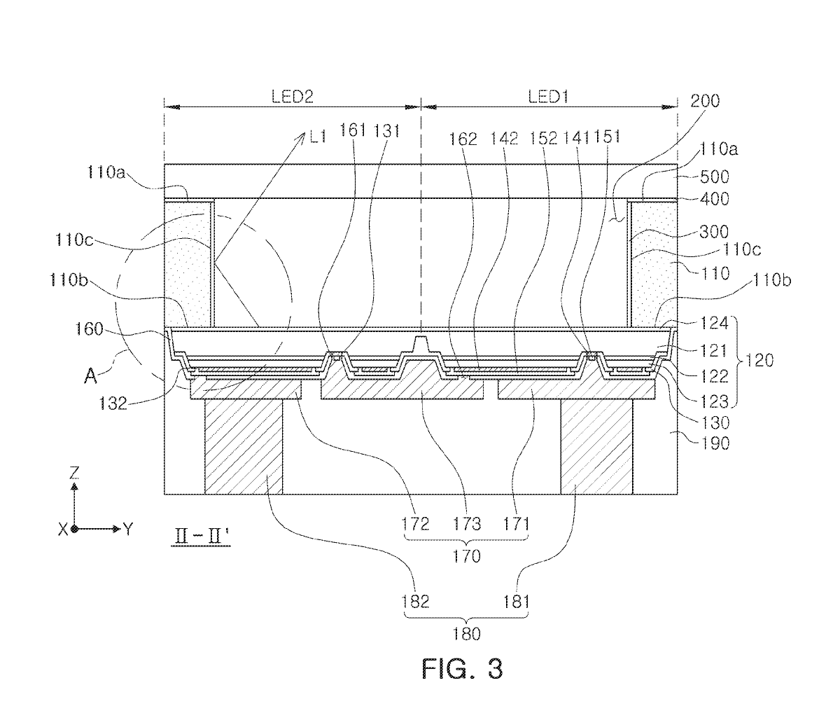

With reference to FIGS. 1 to 3, an ultraviolet light emitting device package 100 according to an example embodiment will be described. FIG. 1 is a schematic, perspective view of a semiconductor light emitting device package according to an example embodiment of the present inventive concepts, FIG. 2 is a top view of a semiconductor light emitting device package of FIG. 1 when viewed in an I direction, and FIG. 3 is a side cross-sectional view taken along line II-II′ of FIG. 2.

With reference to FIGS. 1 to 3, the ultraviolet light emitting device package 100 according to an example embodiment may include a growth substrate 110 having a light emitting window 200, a reflective layer 300, a light transmissive cover 500, a light emitting structure 120 emitting ultraviolet light, a first electrode 141, and/or a second electrode 142. The ultraviolet light emitting device package 100 according to an example embodiment may be provided as a chip scale package (CSP) or a wafer level package (WLP).

The growth substrate 110 may be provided as a semiconductor growth substrate to grow the light emitting structure 120. The growth substrate 110 may be provided in such a manner that the light emitting structure 120 is grown, and then the light emitting window 200 is formed. An insulating material, a conductive material, and a semiconductor material, such as silicon (Si), sapphire, SiC, Ga₂O₃, MgAl₂O₄, MgO, LiAlO₂, LiGaO₂, AlN, and GaN, may be used as the growth substrate 110. In an example embodiment, a Si substrate may be used.

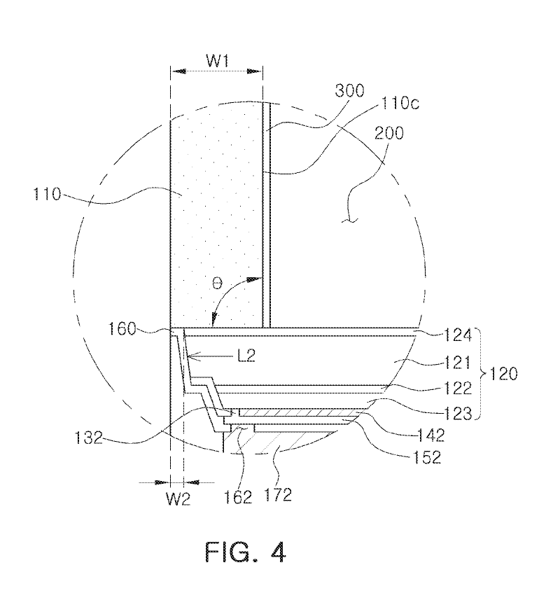

The growth substrate 110 may have a first surface 110a and a second surface 110b, opposing each other, and may have the light emitting window 200 penetrating through an opposing surface. The light emitting window 200 is provided as a region emitting ultraviolet light L1 emitted from the light emitting structure 120 in a forward direction of the ultraviolet light emitting device package 100. As illustrated in FIG. 2, the light emitting window 200 may be formed to have a quadrangular shape surrounded by side walls having a predetermined (and/or desired) thickness W1, when viewed from above, but is not limited thereto. The light emitting window 200 may be variously modified to have a circular shape, an oval shape, and a polygonal shape. As illustrated in FIG. 4, an internal surface 110c of the growth substrate 110 forming the light emitting window 200 may be disposed to be perpendicular to an upper surface of the light emitting structure 120, but is not limited thereto. The internal surface 110c may have a predetermined (and/or desired) angle (θ) to form an inclined surface with respect to the upper surface of the light emitting structure 120.

As illustrated in FIGS. 3 and 4, the reflective layer 300 may be disposed on the internal surface 110c of the growth substrate 110. The reflective layer 300 may be disposed to cover the internal surface 110c and may be extended to the first surface 110a of the growth substrate 110 according to an example embodiment. The reflective layer 300 may reflect the ultraviolet light L1 emitted from the light emitting structure 120 and may concentrate the ultraviolet light L1 in a forward direction of the ultraviolet light emitting device package. In detail, in a case in which a substrate, such as the Si substrate, having a relatively low degree of reflectivity, is employed as the growth substrate 110, the reflective layer 300 may be disposed, thereby reducing or preventing the ultraviolet light L1 from being absorbed by the growth substrate 110 to improve light extraction efficiency.

The reflective layer 300 may be formed using a material including at least one of aluminum (Al), ruthenium (Ru), rhodium (Rh), gold (Au), silver (Ag), platinum (Pt), nickel (Ni), chromium (Cr), titanium (Ti), and copper (Cu), provided as a metal having a relatively high degree of reflectivity.

The light transmissive cover 500 may be disposed on the first surface 110a of the growth substrate 110 to cover the light emitting window 200, thereby sealing the light emitting window 200. The light transmissive cover 500 may have a thin plate shape having a uniform thickness. The light transmissive cover 500 may cover the light emitting window 200, thereby protecting the light emitting structure 120 exposed on a bottom surface of the light emitting window 200 from external moisture. Therefore, the light transmissive cover 500 may cover the light emitting window 200, thereby forming a space portion isolated from an exterior thereof. The space portion may be filled with a material, such as air, different from the light transmissive cover 500. However, a form of the light transmissive cover 500 is not limited thereto. As described in another example embodiment, a lower region of the light transmissive cover 500 may be formed to fill the light emitting window 200, so that the lower region may be disposed to be in contact with the light emitting structure 120.

In addition, as illustrated in FIG. 3, a side surface of the light transmissive cover 500 may be coplanar with a side surface 110d of the growth substrate 110. The light transmissive cover 500 may include one of soft glass, fused silica, and fused quartz. In addition, the light transmissive cover 500 may include low temperature sintered glass obtained by sintering glass frit at a relatively low temperature.

The light transmissive cover 500 may be attached to the first surface 110a of the growth substrate 110 by an adhesive layer 400. The adhesive layer 400 may include a material, such as a silicone resin, an epoxy resin, an acrylic resin, a metal layer, a water glass, or the like. However, the adhesive layer 400 may be omitted. The light transmissive cover 500 may be attached to the first surface 110a of the growth substrate 110 using anodic bonding or fusion bonding. Since the light transmissive cover 500 is formed using a material not easily discolored by ultraviolet light, such as glass or quartz, the light transmissive cover 500 may be reduced or prevented from being discolored by ultraviolet light. Therefore, the ultraviolet light L1 emitted from the light emitting structure 120 may be emitted in a forward direction thereof without loss.

In the ultraviolet light emitting device package 100 according to an example embodiment, the light emitting window 200 may be formed in the growth substrate 110, and the light transmissive cover 500, not discolored by ultraviolet light, may be attached thereto, so that the CSP may be implemented, and light extraction efficiency may be reduced or prevented from being reduced by ultraviolet light. Thus, product reliability of an ultraviolet light emitting device package may be maintained.

The light emitting structure 120 may include a first conductivity-type semiconductor layer 121, an active layer 122, and a second conductivity-type semiconductor layer 123. In addition, according to an example embodiment, the light emitting structure 120 may include a buffer layer 124.

The first conductivity-type semiconductor layer 121 may be provided as an n-type nitride semiconductor satisfying AlₓIn_{y}Ga_{1-x-y}N (0≤x≤1, 0≤y≤1, 0≤x+y≤1), while an n-type impurity may be provided as Si, germanium (Ge), selenium (Se), tellurium (Te), or carbon (C). For example, the first conductivity-type semiconductor layer 121 may include n-type AlGaN, GaN, and GaInN. The second conductivity-type semiconductor layer 123 may be provided as a p-type nitride semiconductor layer satisfying AlₓIn_{y}Ga_{1-x-y}N (0≤x≤1, 0≤y≤1, 0≤x+y≤1). A p-type impurity may be provided as magnesium (Mg), zinc (Zn), and beryllium (Be). For example, the second conductivity-type semiconductor layer 123 may include as p-type AlGaN, GaN, and GaInN. In a specific example, the second conductivity-type semiconductor layer 123 may be a pseudo p-type semiconductor, a nitride semiconductor not intentionally undoped.

The active layer 122 may have a multiple quantum well (MQW) structure in which a quantum well layer and a quantum barrier layer are alternately stacked. For example, the quantum well layer and the quantum barrier layer may be provided as InₓAl_{y}Ga_{1-x-y}N (0≤x≤1, 0≤y≤1, 0≤x+y≤1) having different compositions. In an example embodiment, the MQW, such as GaN/AlGaN, InAlGaN/InAlGaN, and InGaN/AlGaN, may be used. The active layer 122 is not limited to the MQW structure, but may have a single quantum well structure.

The active layer 122 may emit ultraviolet light having a short wavelength. For example, the active layer 122 may be provided as light having a wavelength (λ) Of 200 nm to 430 nm. In a specific example, ultraviolet light emitted from the active layer 122 may be provided as an ultraviolet light-C band (UV-C) having a wavelength of 200 nm to 280 nm. The ultraviolet light has a tendency to be absorbed by a semiconductor (in detail, a semiconductor having a relatively narrow band gap). For example, GaN, may absorb light having a wavelength of 360 nm or less, so that light may be lost. Therefore, a nitride layer, such as AlN and AlGaN, containing Al, may be used as the light emitting structure 120.

The light emitting structure 120 may be disposed as a plurality of light emitting structures. An example embodiment describes a case in which a first light emitting structure LED1 and a second light emitting structure LED2 are provided as an example, but the present inventive concepts are not limited thereto. An example embodiment may include a single light emitting structure and three or more light emitting structures disposed therein.

The buffer layer 124 may be provided between the growth substrate 110 and the first conductivity-type semiconductor layer 121. The buffer layer 124 may be provided as InₓAl_{y}Ga_{1-x-y}N (0≤x≤1, 0≤y≤1). For example, the buffer layer may be formed at a relatively low temperature within a range of 500° C. to 600° C., and may be provided as intentionally undoped GaN, AlN, AlGaN, and InGaN. According to need, the buffer layer 124 may be formed through a composition of a plurality of layers or by gradually changing a composition thereof. The buffer layer 124 may be formed to have a thickness of several tens of nanometers or thousands of nanometers. In an example embodiment, the buffer layer 124 may be formed to have a thickness of 10 nm to 3000 nm.

As illustrated in FIG. 3, the first electrode 141 and the second electrode 142 may be provided to be in contact with the first conductivity-type semiconductor layer 121 and the second conductivity-type semiconductor layer 123, respectively, in the light emitting structure 120.

The first electrode 141 and the second electrode 142 may be formed in such a manner that a conductive material to which the first conductivity-type semiconductor layer 121 and the second conductivity-type semiconductor layer 123 has ohmic contact properties with respect, respectively, is stacked to have a single layer structure or a multilayer structure. For example, the first electrode 141 and the second electrode 142 may be formed in such a manner that one or more materials among Au, Ag, Cu, Zn, Al, indium (In), Ti, Si, Ge, tin (Sn), magnesium (Mg), tantalum (Ta), Cr, tungsten (W), Ru, Rh, iridium (Ir), Ni, palladium (Pd), Pt, a transparent conductive oxide (TCO), and the like, are deposited using a sputtering process. The first electrode 141 and the second electrode 142 may be disposed in the same direction on the other surface opposing one surface on which the first conductivity-type semiconductor layer 121 is disposed, based on the light emitting structure 120. Therefore, the first electrode 141 and the second electrode 142 may be mounted on a surface on which the ultraviolet light emitting device package 100 is mounted, in flip-chip form. In this case, light emitted from the active layer 122 may be emitted outwardly through the first conductivity-type semiconductor layer 121.

A first insulating layer 130 may be disposed on a surface of the light emitting structure 120 to cover the active layer 122 exposed to an etching region and a mesa region. The first insulating layer 130 may basically include a material having insulating characteristics and may be formed using an inorganic or organic material. The first insulating layer 130 may be formed using an epoxy-based insulating resin and may include a silicon oxide or a silicon nitride, such as SiO₂, SiN, SiOₓN_{y}, TiO₂, Si₃N₄, Al₂O₃, TiN, AlN, ZrO₂, TiAlN, and TiSiN.

The first insulating layer 130 may include a plurality of openings 131 and 132 disposed on the first electrode 141 and the second electrode 142, respectively. The plurality of openings 131 and 132 may be defined as positions in which the first electrode 141 and the second electrode 142 are disposed, respectively.

As illustrated in FIGS. 3 and 4, the first electrode 141 may be disposed to be in contact with the first conductivity-type semiconductor layer 121 in the etching region, while the second electrode 142 may be disposed to be in contact with the second conductivity-type semiconductor layer 123 in the mesa region. In addition, the first electrode 141 may include a plurality of pad portions and a finger portion having a width narrower than that of a pad portion. The plurality of pad portions may be disposed to be spaced apart from each other. The second electrode 142 may be provided to cover an upper surface of the second conductivity-type semiconductor layer 123. The second electrode 142 may have a surface area greater than that of the first electrode 141, in consideration of characteristics of the second conductivity-type semiconductor layer 123 having a relatively high level of electrical resistance. The first electrode 141 and the second electrode 142 may be disposed in the plurality of openings 131 and 132, formed by selectively removing the first insulation layer 130 formed on the light emitting structure 120.

A first metal layer 151 and a second metal layer 152 may be disposed to cover the first electrode 141 and the second electrode 142, respectively, to be electrically connected to the first conductivity-type semiconductor layer 121 and the second conductivity-type semiconductor layer 123, respectively. The first metal layer 151 and the second metal layer 152 may be selectively provided and may be omitted depending on an example embodiment.

A second insulating layer 160 may be provided on the light emitting structure 120 to have a structure in which the second insulating layer 160 covers an entirety of the first insulating layer 130, the first metal layer 151, and the second metal layer 152. The second insulating layer 160 may be formed using an epoxy-based insulating resin having basically insulating properties in a manner similar to the first insulating layer 130. In an example embodiment, the second insulating layer 160 may be formed using the same material as the first insulating layer 130.

As illustrated in FIG. 4, the light emitting structure 120 may be etched to be disposed to be spaced apart from a side surface 110d of the growth substrate 110 by a predetermined (and/or desired) width W2, and the second insulating layer 160 may be disposed to be extended to be in contact with the growth substrate 110, thereby reducing or preventing side light L2 of the light emitting structure 120 from being emitted to a side surface of the ultraviolet light emitting device package 100 through the light emitting structure 120.

A bonding structure including a metal pad 170 and a bonding pad 180 may be disposed on the second insulating layer 160.

The metal pad 170 may include a first metal pad 171 and a second metal pad 172, and the first metal pad 171 and the second metal pad 172 may be disposed to be spaced apart from each other on the second insulating layer 160. In addition, the first metal pad 171 and the second metal pad 172 may be electrically connected to the first conductivity-type semiconductor layer 121 and the second conductivity-type semiconductor layer 123, respectively. The metal pad 170 may be provided as a wiring structure to connect the first electrode 141 and the second electrode 142 to the bonding pad 180 to be subsequently described and may include a metal layer having a multilayer or single layer structure. The metal pad 170 may include Cu or a Cu/Sn alloy, but is not limited thereto. The metal pad 170 may include various conductive materials. The first metal pad 171 and the second metal pad 172 may be connected to a first metal layer 151 and a second metal layer 152, respectively, through a plurality of openings 161 and 162 of the second insulating layer 160 in a plurality of regions separated from each other.

As described in an example embodiment, in a case in which the light emitting structure 120 includes a plurality of light emitting structures LED1 and LED2, connection metal pads 173 may be disposed to be spaced apart from each other between the first metal pad 171 and the second metal pad 172. A connection metal pad 173 may penetrate through the second insulating layer 160 to connect the first electrode 141 of a light emitting structure LED2 of a plurality of light emitting structures to the second electrode 142 of another light emitting structure LED1 disposed adjacent thereto, thereby electrically connecting the plurality of light emitting structures LED1 and LED2.

The bonding pad 180 may include a first bonding pad 181 and a second bonding pad 182. The first bonding pad 181 and the second bonding pad 182 may be disposed on the first metal pad 171 and the second metal pad 172, respectively. The bonding pad 180 is a solder-attached portion when the ultraviolet light emitting device package 100 is mounted on a circuit board and is connected to the first conductivity-type semiconductor layer 121 and the second conductivity-type semiconductor layer 123, thereby applying an electric current supplied through the bonding pad 180 to the first conductivity-type semiconductor layer 121 and the second conductivity-type semiconductor layer 123. The bonding pad 180 may be formed using a material the same as the first metal pad 171 and the second metal pad 172.

An encapsulant 190 may be disposed to cover the metal pad 170 and the bonding pad 180, bonding structures. In addition, the encapsulant 190 may be disposed to cover the light emitting structure 120. The encapsulant 190 may be formed to have a flat surface exposing a surface of the first bonding pad 181 and the second bonding pad 182. The encapsulant 190 may have a high Young's modulus to firmly support the first light emitting structure LED1 and the second light emitting structure LED2. In addition, the encapsulant 190 may include a material having a high thermal conductivity to effectively emit heat generated in the first light emitting structure LED1 and the second light emitting structure LED2. For example, the encapsulant 190 may include a material including an epoxy resin, an acrylic resin, or a silicone resin. In addition, the encapsulant 190 may include reflective particles to reflect light. Titanium dioxide (TiO₂) or aluminum oxide (Al₂O₃) may be used as the reflective particles, but the present inventive concepts are not limited thereto. In addition, as illustrated in FIG. 3, a side surface of the encapsulant 190 may be formed to be coplanar with a side surface 110b of the growth substrate 110.

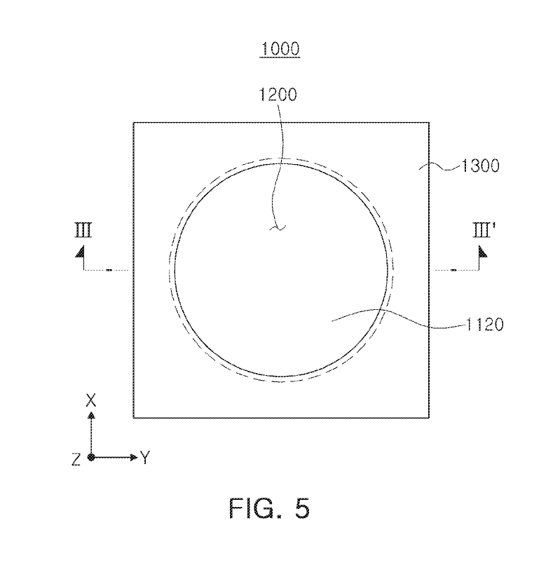

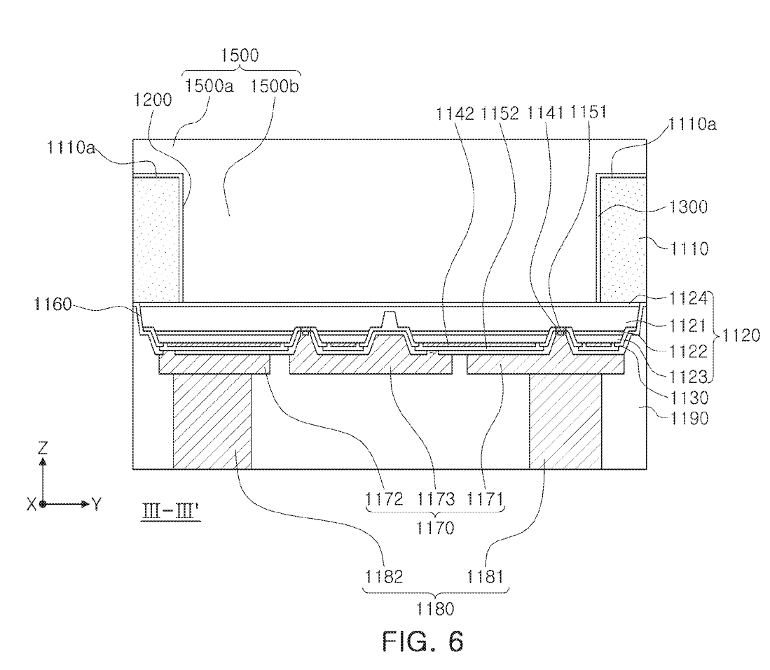

Subsequently, an example embodiment of the ultraviolet light emitting device package 100 will be described. FIG. 5 is a top view of a light emitting device package according to an example embodiment, while FIG. 6 is a cross-sectional view of an ultraviolet light emitting device package taken along line of FIG. 5.

The ultraviolet light emitting device package 1000 according to an example embodiment is similar to an example embodiment described above, in that the ultraviolet light emitting device package 1000 includes a growth substrate 1110 having a light emitting window 1200, a reflective layer 1300, a light transmissive cover 1500, a light emitting structure 1120 emitting ultraviolet light, a first electrode 1141, and/or a second electrode 1142. However, the ultraviolet light emitting device package 1000 is different, in that a lower portion of the light transmissive cover 1500 fills the light emitting window 1200 to be in contact with the light emitting structure 1120, and a form of the reflective layer 1300 is different. In addition, when viewed from above, there is a difference in which the light emitting window 1200 is formed to be circular.

In a manner similar to an example embodiment described above, the light emitting structure 1120 may include a first conductivity-type semiconductor layer 1121, an active layer 1122, a second conductivity-type semiconductor layer 1123, and/or a buffer layer 1124. In addition, since a first insulating layer 1130, a second insulating layer 1160, a first metal layer 1151, a second metal layer 1152, a first metal pad 1171, a second metal pad 1172, a connection metal pad 1173, a first bonding pad 1181, a second bonding pad 1182 and/or a encapsulant 1190 are the same as an example embodiment described above, detailed descriptions thereof will be omitted.

In an example embodiment, the reflective layer 1300 may be disposed to cover a side wall of the light emitting window 1200 and an upper surface 1110a of the growth substrate 1110. Therefore, a portion of ultraviolet light incident on the light transmissive cover 1500 may be reduced or prevented from being absorbed by the upper surface 1110a of the growth substrate 1110.

In the case of an example embodiment, the light transmissive cover 1500 may include an upper region 1500a having a flat surface and a lower region 1500b protruding to fill the light emitting window 1200 in the upper portion 1500a. The light transmissive cover 500 may include low temperature sintered glass obtained by sintering glass frit at a relatively low temperature. The light transmissive cover 1500 may be formed by filling a mixture layer containing a glass composition to cover the growth substrate 1110 and sintering the mixture layer at a temperature of 750° C. or lower.

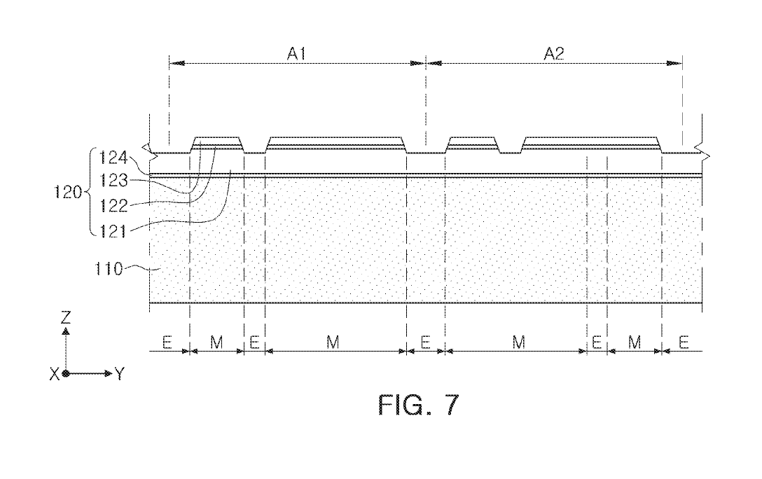

Subsequently, a process of manufacturing an ultraviolet light emitting device package 100 of FIG. 1 will be described. FIGS. 7 to 17 are schematic cross-sectional views of a method of manufacturing an ultraviolet light emitting device package of FIG. 3. In FIGS. 7 to 17, the same reference numerals as in FIGS. 1 to 3 denote the same members, and thus, overlapping descriptions will be omitted.

With reference to FIG. 7, a first conductivity-type semiconductor layer 121, an active layer 122, and/or a second conductivity-type semiconductor layer 123 may be sequentially epitaxially grown on a growth substrate 110 to form a light emitting structure 120. The second conductivity-type semiconductor layer 123, the active layer 122, and the first conductivity-type semiconductor layer 121 may be partially etched so that at least a portion of the first conductivity-type semiconductor layer 121 may be exposed. Thus, an etching region E, as well as a plurality of mesa regions M partially partitioned by the etching region E, may be formed. An example embodiment describes a case in which two light emitting structures include regions A1 and A2 to be formed, as an example.

The growth substrate 110 may be provided as one of Si, sapphire, SiC, Ga₂O₃, MgAl₂O₄, MgO, LiAlO₂, LiGaO₂, AlN, and GaN. A buffer layer 124 may be provided between the growth substrate 110 and the first conductivity-type semiconductor layer 121. The buffer layer 124 may be InₓAl_{y}Ga_{1-x-y}N (0≤x≤1, 0≤y≤1). For example, the buffer layer 124 may be formed at a relatively low temperature within a range of 500° C. to 600° C. and may be provided as intentionally undoped GaN, AlN, AlGaN, and InGaN. According to need, the buffer layer 124 may be formed through a composition of a plurality of layers or by gradually changing a composition thereof.

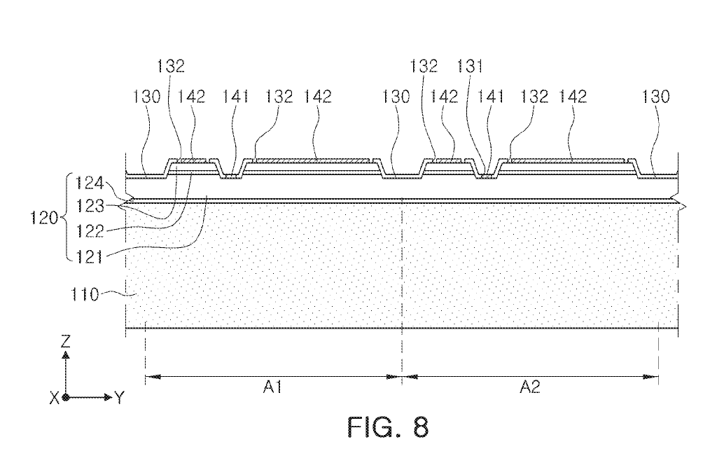

Subsequently, with reference to FIG. 8, an insulating material may be deposited on a light emitting structure 120 to form a first insulating layer 130, and a region of the first insulating layer 130 may be etched, so that openings 131 and 132 exposing a first conductivity-type semiconductor layer 121 and a second conductivity-type semiconductor layer 123 may be formed, and a conductive metal may be deposited on each of the openings 131 and 132 to form a first electrode 141 and a second electrode 142.

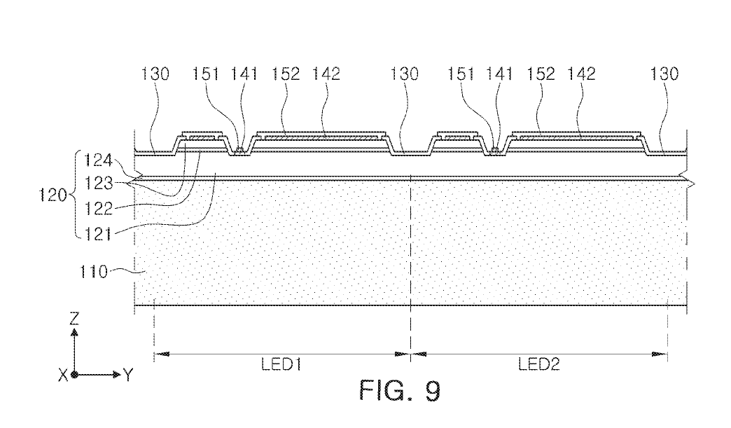

With reference to FIG. 9, a conductive metal may be deposited on each of a first electrode 141 and a second electrode 142 to form a metal layer 151 and a second metal layer 152, thereby providing a first light emitting structure LED1 and a second light emitting structure LED2.

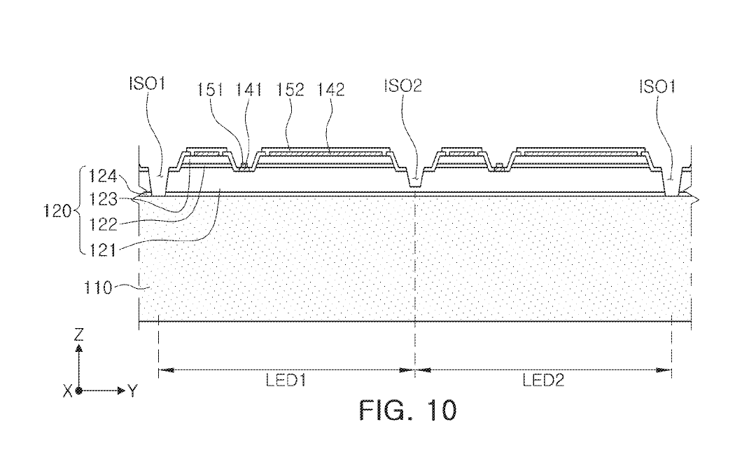

With reference to FIG. 10, a region of a light emitting structure 120 may be etched, thereby forming an device isolation region ISO1 in which a growth substrate 110 is exposed and a light emitting structure isolation region ISO2 in which a first conductivity-type semiconductor layer 121 is exposed.

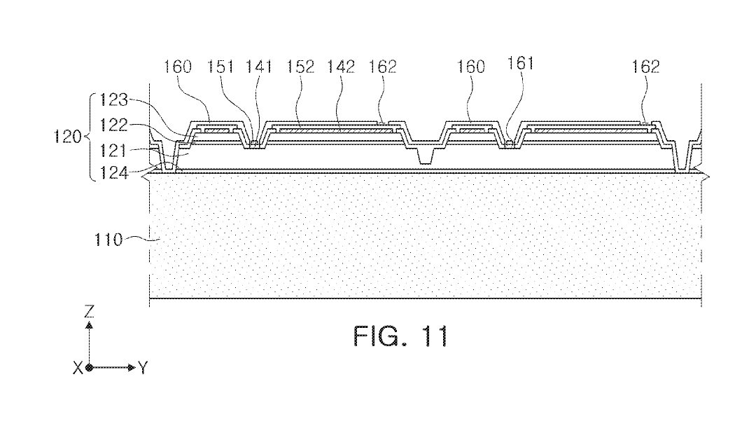

With reference to FIG. 11, a second insulating layer 160 may be formed by depositing an insulating material to cover a first metal layer 151 and a second metal layer 152. A region of the second insulating layer 160 may be etched, thereby forming openings 161 and 162 exposing a first metal layer 151 and a second metal layer 152.

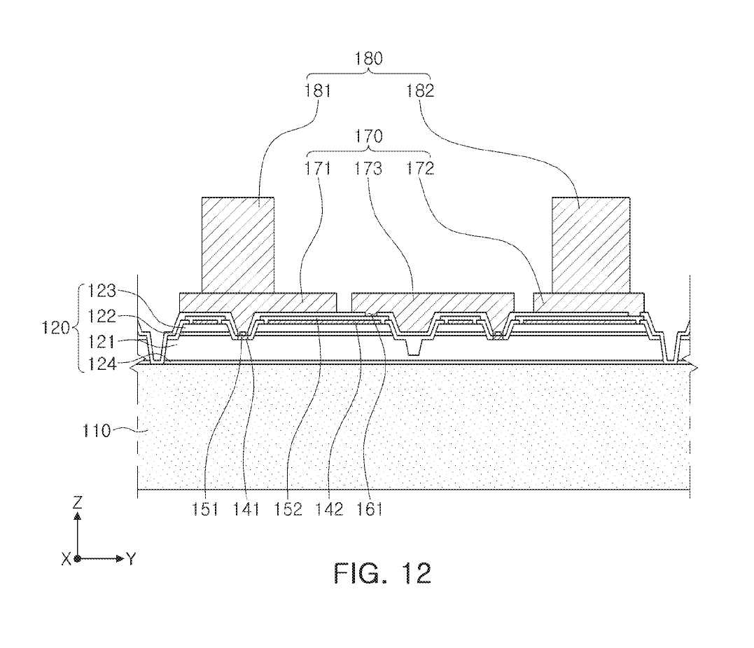

With reference to FIG. 12, a bonding structure including a metal pad 170 and a bonding pad 180 may be formed on a second insulating layer 160. The metal pad 170 may include a first metal pad 171, a second metal pad 172, and a connection metal pad 173. The bonding pad 180 may include a first bonding pad 181 and a second bonding pad 182. The first metal pad 171, the second metal pad 172, and the connection metal pad 173 may be formed by a plating process using a seed layer. The first metal pad 171 and the second metal pad 172 may be formed to be spaced apart from each other not to be electrically short-circuited. The first metal pad 171, the second metal pad 172, and the connection metal pad 173 may be formed using Cu, but are not limited thereto. The first metal pad 171, the second metal pad 172, and the connection metal pad 173 may be formed using a conductive material not including Cu.

The first bonding pad 181 and the second bonding pad 182 may be formed on the first metal pad 171 and the second metal pad 172. The first bonding pad 181 and the second bonding pad 182 may be formed using the plating process. The first bonding pad 181 and the second bonding pad 182 may be formed using the same material as the first metal pad 171 and the second metal pad 172.

A photoresist pattern defined as a region in which the first metal pad 171 and the second metal pad 172 are formed or a region in which the first bonding pad 181 and the second bonding pad 182 are formed may be formed to perform the plating process. The photoresist pattern may be removed by a strip process after the plating process is completed.

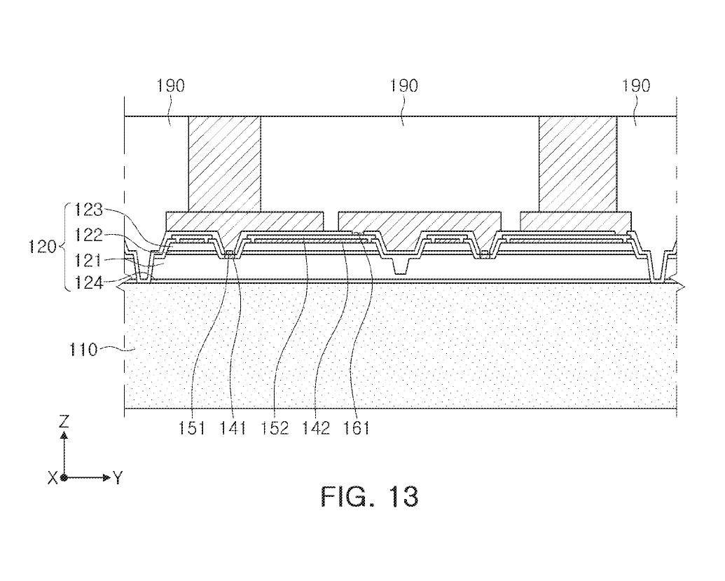

With reference to FIG. 13, an encapsulant 190 encapsulating the first metal pad 171, the second metal pad 172, the first bonding pad 181, and the second bonding pad 182 may be formed.

The encapsulant 190 may include a process of coating an encapsulating material so as to cover even upper portions of the first bonding pad 181 and the second bonding pad 182. The encapsulant 190 may also include a process of exposing end portions of the first bonding pad 181 and the second bonding pad 182 selectively using a polishing process, such as grinding.

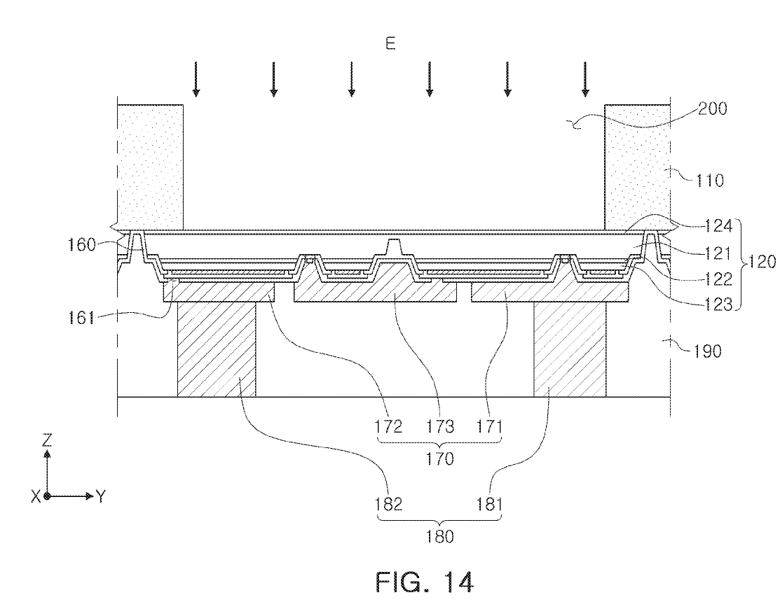

With reference to FIG. 14, a central region of a growth substrate 110 may be etched to be removed to expose a bottom surface of a first conductivity-type semiconductor layer 121, thereby forming a light emitting window 200. In this case, a portion of a buffer layer 124 may remain on the bottom surface, depending on an example embodiment. The light emitting window 200 may be formed by a dry etching process of the growth substrate 110, such as an oxide-deep reactive ion etching (oxide-DRIE) process. However, in addition to a method described above, various dry or wet etching processes used in the related art may be used. The light emitting window 200 may also be formed using a laser-drilling method.

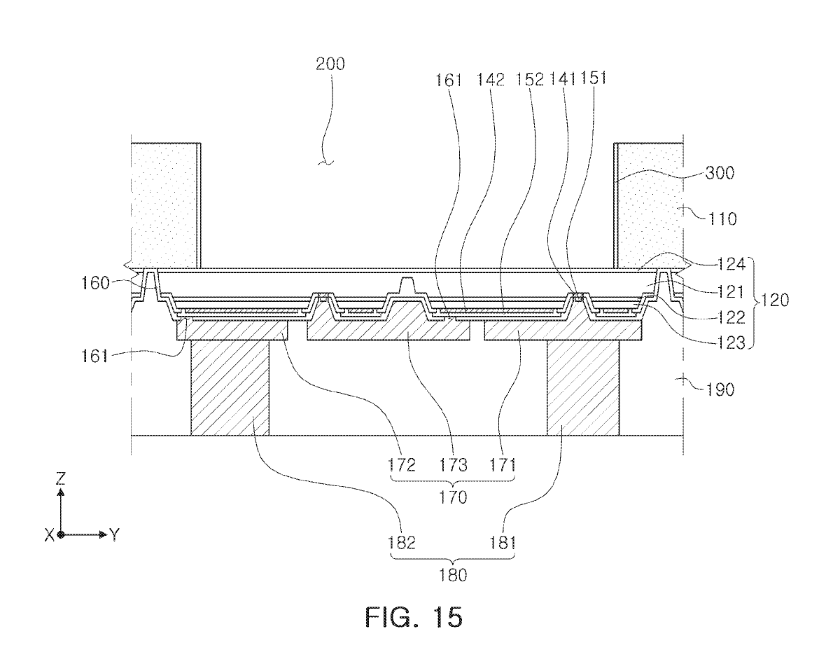

Subsequently, with reference to FIG. 15, a reflective layer 300 may be formed on an internal surface of a growth substrate 110, thereby allowing the reflective layer 300 to be disposed in the light emitting window 200. The reflective layer 300 may be formed using a material including at least one of Al, Ru, Rh, Au, Ag, Pt, Ni, Cr, Ti, and Cu, provided as a metal having a relatively high degree of reflectivity.

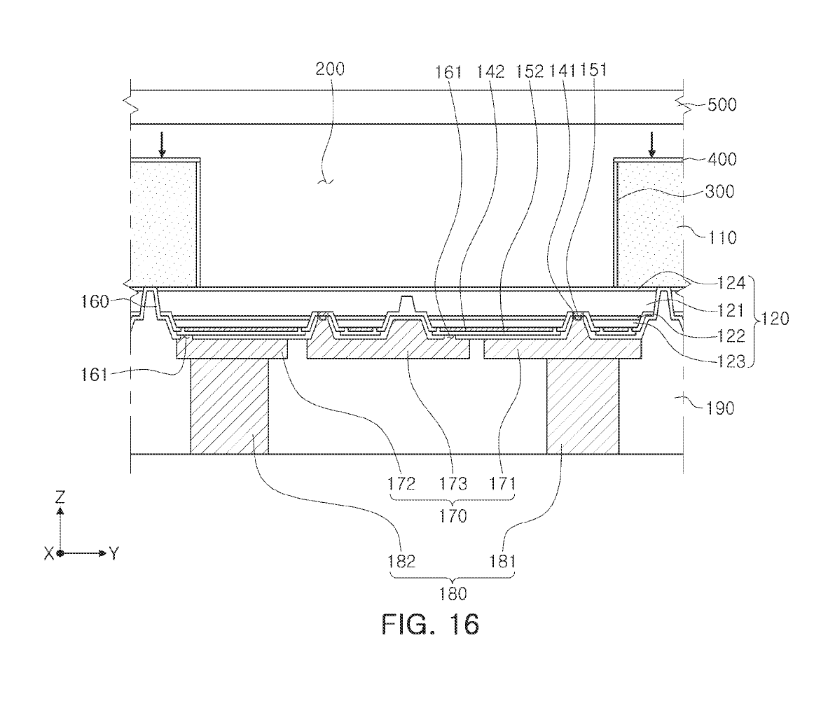

With reference to FIG. 16, a light transmissive cover 500 may be attached to cover a light emitting window 200. The light transmissive cover 500 may include one of soft glass, fused silica, and fused quartz. In the case of the light transmissive cover 500, a material, such as a silicone resin, an epoxy resin, an acrylic resin, a metal layer, and water glass may be coated on an upper surface of the growth substrate 110 to be attached thereto. However, an adhesive layer 400 may be omitted. The light transmissive cover 500 may be attached to a first surface 110a of the growth substrate 110 using anodic bonding or fusion bonding.

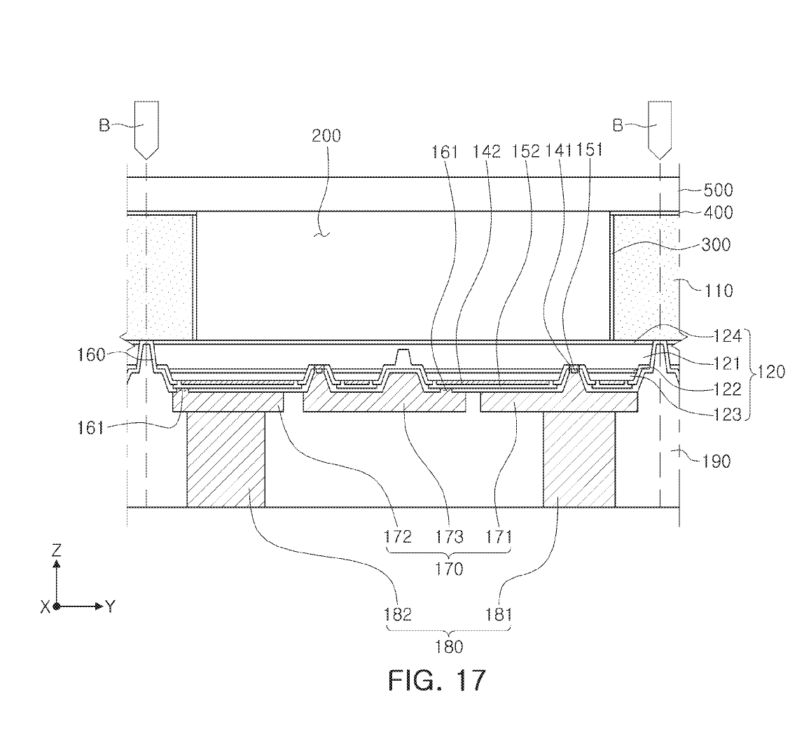

With reference to FIG. 17, a process of cutting an ultraviolet light emitting device package by an individual package using a blade B, thereby forming the ultraviolet light emitting device package illustrated in FIG. 1.

As set forth above, according to example embodiments of the present inventive concepts, an ultraviolet light emitting device package may improve light extraction efficiency in such a manner that a reflective layer is disposed on an internal wall of a light emitting window.

While example embodiments have been shown and described above, it will be apparent to those skilled in the art that modifications and variations could be made without departing from the scope of the present inventive concepts as defined by the appended claims.

What is claimed is:

1. An ultraviolet light emitting device package, comprising:
a growth substrate having a first surface, a second surface corresponding to the first surface, and a light emitting window penetrating through the first surface and the second surface;
a reflective layer on an internal wall of the light emitting window;
a light transmissive cover on the first surface and covering the light emitting window;
a light emitting structure on the second surface to cover the light emitting window, and including a first conductivity-type semiconductor layer, a second conductivity-type semiconductor layer, and an active layer between the first conductivity-type semiconductor layer and the second conductivity-type semiconductor layer; and
a first electrode and a second electrode, connected to the first conductivity-type semiconductor layer and the second conductivity-type semiconductor layer, respectively.

2. The ultraviolet light emitting device package of claim 1, wherein a wavelength of light emitted from the active layer is within a range of 200 nm to 280 nm.

3. The ultraviolet light emitting device package of claim 1, wherein the light transmissive cover is formed of one of soft glass, fused silica, and fused quartz.

4. The ultraviolet light emitting device package of claim 1, wherein the light transmissive cover is attached by an adhesive layer coated on the first surface of the growth substrate.

5. The ultraviolet light emitting device package of claim 4, wherein the adhesive layer is formed of a material including at least one of a silicone resin, an epoxy resin, an acrylic resin, a metal layer, and a water glass.

6. The ultraviolet light emitting device package of claim 1, wherein the reflective layer is formed of a material including at least one of aluminum (Al), ruthenium (Ru), rhodium (Rh), gold (Au), silver (Ag), platinum (Pt), nickel (Ni), chromium (Cr), titanium (Ti), and copper (Cu).

7. The ultraviolet light emitting device package of claim 1, wherein the reflective layer extends to the first surface.

8. The ultraviolet light emitting device package of claim 1, wherein a side surface of the growth substrate is coplanar with a side surface of the light transmissive cover.

9. The ultraviolet light emitting device package of claim 1, wherein the light transmissive cover comprises an upper region having a flat surface and a lower region protruding toward the light emitting window from the upper region, and the lower region is in contact with the light emitting structure to fill the light emitting window.

10. The ultraviolet light emitting device package of claim 9, wherein the light transmissive cover is formed of low temperature sintered glass obtained by sintering glass frit at a relatively low temperature.

11. The ultraviolet light emitting device package of claim 1, wherein the light transmissive cover covers the light emitting window to form a space portion.

12. The ultraviolet light emitting device package of claim 11, wherein the space portion is filled with a material different from a material forming the light transmissive cover.

13. The ultraviolet light emitting device package of claim 12, wherein the space portion is filled with air.

14. The ultraviolet light emitting device package of claim 1, further comprising a first electrode and a second electrode, on the light emitting structure and connected to the first conductivity-type semiconductor layer and the second conductivity-type semiconductor layer, respectively; an insulating layer covering the light emitting structure, the first electrode, and the second electrode; a first metal pad and a second metal pad, on the insulating layer and penetrating through the insulating layer to be connected to the first electrode and the second electrode, respectively; a first bonding pad and a second bonding pad, on the first metal pad and the second metal pad, respectively; and a encapsulant covering the first bonding pad, the second bonding pad, and the first metal pad to expose a portion of the first and second bonding pads.

15. The ultraviolet light emitting device package of claim 14, wherein at least a portion of the insulating layer is in contact with the growth substrate.

16. The ultraviolet light emitting device package of claim 14, wherein a side surface of the encapsulant is coplanar with a side surface of the growth substrate.

17. An ultraviolet light emitting device package, comprising:
a growth substrate, including at least one light emitting window penetrating through the growth substrate in a thickness direction;
a reflective layer covering an internal wall of the at least one light emitting window;
a light transmissive cover on one surface of the growth substrate and covering the at least one light emitting window to form a blocked space;
at least one light emitting structure on the other surface of the growth substrate to cover the at least one light emitting window, and including a first conductivity-type semiconductor layer, an active layer, and a second conductivity-type semiconductor layer, sequentially arranged on the other surface; and
a first electrode and a second electrode, connected to the first conductivity-type semiconductor layer and the second conductivity-type semiconductor layer of the at least one light emitting structure, respectively.

18. The ultraviolet light emitting device package of claim 17, wherein the internal wall of the light emitting window forms an inclination angle with respect to an interface of the first conductivity-type semiconductor layer.

19. An ultraviolet light emitting device package, comprising:
a light emitting structure including a first conductivity-type semiconductor layer, an active layer, and a second conductivity-type semiconductor layer;
a growth substrate having one surface in contact with the light emitting structure, the other surface opposing the one surface, and a light emitting window defined by an internal wall penetrating through the one surface and the other surface;
a reflective layer covering the internal wall;
a light transmissive cover on the other surface of the light emitting structure and covering the light emitting window; and
a first electrode and a second electrode, connected to the first conductivity-type semiconductor layer and the second conductivity-type semiconductor layer, respectively.

20. The ultraviolet light emitting device package of claim 19, wherein the growth substrate is formed of a material including silicon (Si).
